(19) United States
(12) Patent Application Publication
(10) Pub. No.: US 2018/0291494 A1
(43) Pub. Date: Oct. 11, 2018

(54) SHADOW MASK ASSEMBLIES AND REUSING METHODS OF SHADOW MASK ASSEMBLIES THEREOF

(71) Applicant: WUHAN CHINA STAR OPTOELECTRONICS TECHNOLOGY CO., LTD., Wuhan, Hubei (CN)

(72) Inventor: Xuwen CAO, Shenzhen, Guangdong (CN)

(73) Assignee: Wuhan China Star Optoelectronics Technology Co., Ltd., Wuhan, Hubei (CN)

(21) Appl. No.: 15/526,292

(22) PCT Filed: Mar. 2, 2017
(86) PCT No.: PCT/CN2017/075461

§ 371 Date: May 11, 2017

(30) Foreign Application Priority Data
Feb. 15, 2017 (CN) 201710082092.6

(51) Int. Cl. C23C 14/04; C03C 17/00; C23C 14/24

(52) U.S. Cl. CPC C23C 14/042; C03C 17/002; C03C 2218/34; C03C 2218/151; C23C 14/24

(57) ABSTRACT

The present disclosure relates to a shadow mask assembly including a shadow mask film and a frame. The frame includes an outer wall, an inner wall arranged opposite to the outer wall, and a bonding surface connecting the outer wall and the inner wall, wherein the bonding surface bonds with the shadow mask film. The bonding surface includes a welding area and a tiling area, wherein the welding area and the tiling area are non-coplanar. The welding area is arranged between the tiling area and the outer wall. The frame is fixed on at least one edge of the shadow mask film via at least one solder joint arranged within the welding area. The tiling area is arranged between the welding area and the inner wall, and the tiling area is configured to support the shadow mask film and to maintain the shadow mask film to be a flat surface.

### CROSS REFERENCE

This application claims the priority of Chinese Patent Application No. 2017100820926, entitled “Shadow mask assemblies and reusing methods of shadow mask assemblies thereof”, filed on Feb. 15, 2017, the disclosure of which is incorporated herein by reference in its entirety.

### FIELD OF THE INVENTION

The present disclosure relates to liquid crystal manufacturing field, more particularly to a shadow mask assembly and are using method of shadow mask assemblies.

### BACKGROUND OF THE INVENTION

The production of the display panel of active-matrix organic light emitting diode (AMOLED) displays requires a thin fine metal mask (FMM) having small thermal expansion coefficient as a shadow mask film (also referred to as mask plate) to deposit the organic light emitting diode in the display panel pixels. Usually, the thickness of the shadow mask film is merely 30-200 μm, which is thin and brittle. When bonding the shadow mask film on the surface of the substrate, wherein the organic luminous pixels are deposited on the substrate, due to the demanding of maintaining high position accuracy, usually, adopting laser to weld the shadow mask film on a metal frame to stretch the shadow mask film and to form a shadow mask assembly. The shadow mask film has been well stretched during welding, however, due to the area of the shadow mask film is large, after using for a plurality of time, the shadow mask film still sags due to the effect of the gravity, and causing certain detachment in between the mask and the deposited surface during the deposition process, such that the deposition accuracy decrease. When the tension of the shadow mask film is not enough or the shadow mask film has defects during the operation process which lead to the shadow mask film is not capable of being used, usually, the mask may be removed and the frame may be recycled, and a new shadow mask is re-welded to the frame to form a new shadow mask assembly for continued use.

Conventionally, the shadow mask film is arranged on the frame, and the surface where the frame and the shadow mask film are welded is parallel to the shadow mask film. Each times of replacing a new shadow mask film, polishing the solder joints of the original shadow mask film on the frame is required. The poor polishing result may lead to a poor flatness of the surface where the solder joints are arranged, the more times of polishing process, and the influence becomes more obvious. Thus affecting the flatness of the shadow mask film and causing a non-accurate alignment between the shadow mask film and the substrate where the AMOLED is deposited, such that decreasing the AMOLED glass substrate yield and increasing the production cost.

### SUMMARY OF THE INVENTION

The present disclosure relates to a shadow mask film assembly and a reusing method of shadow mask assemblies that are capable of enhancing the yield rate of vapor processes of AMOLED glass substrates.

A shadow mask assembly, including: a shadow mask film and a frame, and the frame includes an outer wall, an inner wall arranged opposite to the outer wall, and a bonding surface connecting the outer wall and the inner wall, wherein the bonding surface bonds with the shadow mask film. The bonding surface includes a welding area and a tiling area, wherein the welding area and the tiling area are non-coplanar. The welding area is arranged between the tiling area and the outer wall, and the frame is fixed on at least one edge of the shadow mask film via at least one solder joint arranged within the welding area. The tiling area is arranged between the welding area and the inner wall, and the tiling area is configured to support the shadow mask film and to maintain the shadow mask film to be a flat surface.

The shadow mask film includes an operation part and a non-operation part connecting to an edge of the operation part, the non-operation part bonds with the bonding surface. The non-operation part includes a fixing part and a transition part, the transition part is arranged between the operation part and the fixing part. The fixing part is welded to the welding area of the frame and keeps the operation part in a tight state. The transition part bonds with the tiling area and is configured to maintain a flatness of the operation part. A side surface of the operation part facing away from the frame is configured to bond with a glass substrate of a display device and is configured to apply a vapor deposition process to the glass substrate.

The frame further includes a bottom surface, wherein the bottom surface is opposite to the tiling area and connects the outer wall and the inner wall, and the welding area is bent toward the bottom surface with respect to the tiling area.

A cross-section of the welding area is an arc connecting the tiling area and the outer wall.

The solder joint is also arranged on a sidewall, and the fixing part is fixed on the frame via the solder joint on the sidewall.

A cross-section of the sidewall is an arc having a curvature equal to the welding area. A continuous arc is formed by the cross-section of the welding area and the cross-section of the sidewall, and the continuous arc connects the tiling area and the bottom surface.

The bottom surface is also configured with the solder joints, and the fixing part is fixed on the frame via the solder joint on the bottom surface.

A reusing method of shadow mask assemblies, including: providing a shadow mask film and a frame, and the frame includes an outer wall, an inner wall arranged opposite to the outer wall, and a bonding surface connecting the outer wall and the inner wall. The bonding surface includes a welding area and a tiling area, wherein the welding area and the tiling area are non-coplanar. The welding area is arranged between the tiling area and the outer wall, and the tiling area is arranged between the welding area and the inner wall. Fixing the frame on at least one edge of the shadow mask film via the welding area, and at least one solder joint is arranged within the welding area. The frame maintains the shadow mask film to be a flat surface via the tiling area. Bonding a glass substrate of a display device via the shadow mask film and applying a vapor deposition process to the glass substrate. Removing the shadow mask film from the frame upon changing the shadow mask film. Forming a new solder joint by welding another shadow mask film onto the welding area. Applying a polishing process to all of the solder joints at one time after the shadow mask films have been changed for a plurality of times.

The frame includes a bottom surface, wherein the bottom surface is opposite to the tiling area and connects the outer wall and the inner wall, and the welding area is bent toward the bottom surface with respect to the tiling area.

A cross-section of the welding area is an arc connecting the tiling area and the outer wall.

The solder joint is also arranged on a sidewall, the fixing part is fixed on the frame via the solder joint on the sidewall.

A cross-section of the sidewall is an arc having a curvature equal to the welding area, a continuous arc is formed between the cross-section of the welding area and the cross-section of the sidewall, and the continuous arc connects the tiling area and the bottom surface.

The bottom surface is also configured with the solder joint, and the fixing part is fixed on the frame via the solder joint on the bottom surface.

In another aspect, with respect to the shadow mask film assembly and a reusing methods of shadow mask assemblies, the bonding surface is divided into the welding area configured to weld the shadow mask film and the tiling area configured to expand the shadow mask film, and the welding area and the tiling area are non-coplanar. The welding area is configured to fix and stretch the shadow mask film, and the shadow mask film bonds with the tiling area to maintain the shadow mask film to be a flat surface. At least one solder joint of the original shadow mask film remains on the welding area has no influence on the flatness of the shadow mask film upon changing a new shadow mask film, such that to enhance the deposition yield of AMOLED glass substrates and to reduce the production cost.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a schematic view of a cross-section of a shadow mask assembly in accordance with a first embodiment of the present disclosure.

FIG. 2 is a schematic view of a cross-section of the shadow mask assembly in accordance with a second embodiment of the present disclosure.

FIG. 3 is a schematic view of a cross-section of a shadow mask assembly in accordance with a third embodiment of the present disclosure.

FIG. 4 is a schematic view of a cross-section of a shadow mask assembly in accordance with a fourth embodiment of the present disclosure.

FIGS. 5 to 9 are schematic views illustrating the steps of are using method of shadow mask assemblies in accordance with one embodiment of the present disclosure.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained should be considered within the scope of protection of the present invention.

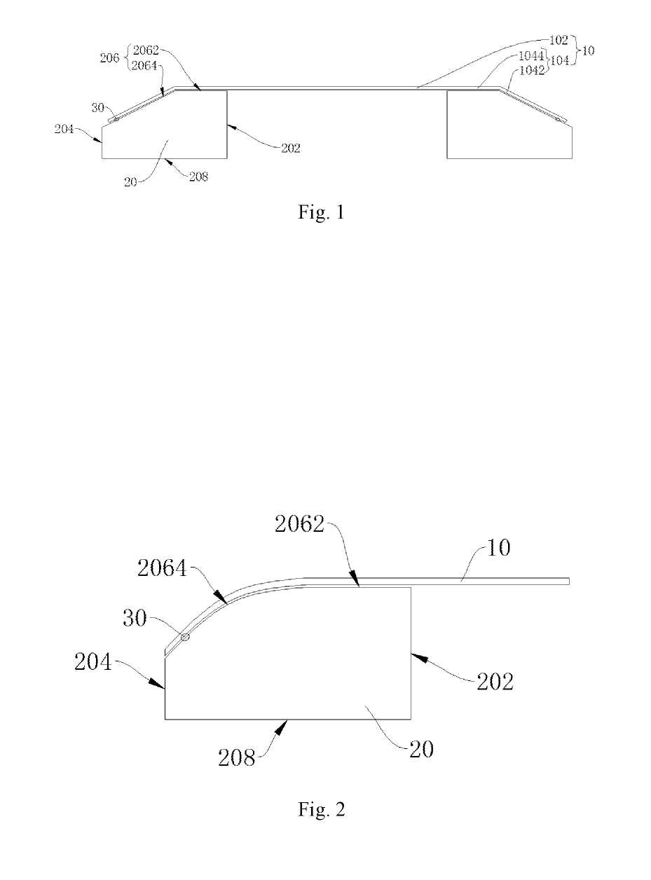

FIG. 1 is a schematic view of a cross-section of a shadow mask assembly in accordance with one embodiment of the present disclosure. The shadow mask assembly includes a shadow mask film 10 and a frame 20. The shadow mask film 10 is connected to the frame 20 via welding at least one edge of the shadow mask film 10 to a surface of the frame 20, wherein the frame 20 is made of metal materials with high strength. The shadow mask film 10 is expanded and stretched by a tension which is even and pointing to the surroundings due to a stable structure of the frame 20. Specifically, the shadow mask film 10 is rectangle shape, and the frame 20 is a rectangular box fitting a size of the shadow mask film 10. Four brackets of the frame 20 are fixed on the corresponding edge of four sides of the shadow mask film 10, thereby to stretch the shadow mask film 10 toward the four sides of the shadow mask film 10. Such that to tile and expand the shadow mask film 10, and to form a tight surface. A method of fixing the edges of the shadow mask film 10 by the frame 20 and stretching the shadow mask film 10 from the sides of the shadow mask film 10 is not only can completely expand the shadow mask film 10 and maintain the shadow mask film 10 to be a flat surface, but reduce an area of a contact surface and reduce an influence between a flatness of a contact surface of the frame 20 and the shadow mask film 10 and a flatness of the shadow mask film 10. Thereby facilitating the alignment and bonding of the shadow mask film 10 with an AMOLED glass substrate, enhancing a yield of the AMOLED glass substrates, and reducing production cost.

The frame 20 further includes an outer wall 204, an inner wall 202 arranged opposite to the outer wall 204, and a bonding surface 206 connecting the outer wall 204 and the inner wall 202. Specifically, the outer wall 204 is a surface of the frame 20 facing away from a center of the frame 20. The inner wall 202 is a surface of the frame 20 facing toward from the center of the frame 20. The bonding surface 206 bonds with the shadow mask film 10, and a bonding surface 206 includes a welding area 2064 and a tiling area 2062, wherein then welding area 2064 and the tiling area 2062 are non-coplanar. In one embodiment, the tiling area 2062 is a flat surface perpendicular to the inner wall 202. Further, when the welding area 2064 is also a flat surface, the welding area 2064 is inclined to the tiling area 2062. When the welding area 2064 is a curve, the welding area 2064does not intersect with the tiling area 2062 except a junction of the welding area 2064 and tiling area 2062. It is also understood that a direction of the tension applied on the shadow mask film 10 by the solder joint 30 is parallel to a surface of the weld area 2064, so that the direction of the tension is not parallel to an expanding direction of the shadow mask film 10. The weld area 2064 is arranged between the tiling area 2062 and the welding area 2064. The frame 20 is fixed on the edge of the shadow mask film 10 via at least one solder join 30, wherein the solder join 30 is configured within the welding area 2064. The tiling area 2062 is arranged between the welding area 2064 and the inner wall 202, and the tiling area 2062 is configured to expand and tile the shadow mask film 10. Further, the edges of the shadow mask film 10 are supported by the tiling area 2062, and the tiling area 2062 is configured to assist in maintaining a flatness of the mask film 10, and is configured to prevent the AMOLED glass substrate bonding with the mask film 10 from deformation. At the same time, the shadow mask film 10 is stretched by the solder joint 30 within the welding area 2064, and the shadow mask film 10 bonds with the tiling area 2062. The tiling area 2062 converts the tension, applied from the solder join 30 to the shadow mask film 10, from a direction parallel to the surface of the weld area 2064 to an expanding direction of the shadow mask film 10.

The bonding surface 206 is divided into the welding area 2064 configured to weld the shadow mask film 10 and the tiling area 2062 configured to expand the shadow mask film 10, and the welding area 2064 and the tiling area 2062 are non-coplanar. The welding area 2064 is configured to fix and stretch the shadow mask film 10, and the shadow mask film 10 bonds with the tiling area 2062 to maintain the shadow mask film 10 to be a flat surface. The solder joint 30 of the original shadow mask film remains on the welding area 2064 has no influence on the flatness of the shadow mask film 10 upon changing a new shadow mask film 10, such that to enhance the deposition yield of AMOLED glass substrates and to reduce the production cost. On the other hand, due to the non-planar between the welding area 2064 and the tiling area 2062, and the non-planar between the welding area 2064 and an expanded surface of the shadow mask film 10, a height of the solder joint 30 within the welding area 2064 may not have influence on the flatness of a surface of the shadow mask film 10, wherein the surface is configured to bond with the glass substrate. Such that a gap between the shadow mask film 10 and the glass substrate may be avoided, and lead to a pixel shading increasing when applying a vapor deposition process to the glass substrate, thereby to enhance the yield of the AMOLED glass substrates.

In one embodiment, the shadow mask film 10 includes an operation part 102 and a non-operation part 104 connecting to an edge of the operation part 102, and the non-operation part 104 bonds with the bonding surface 206.The non-operation part 104 includes a fixing part 1042 and a transition part 1044, wherein the transition part 1044 is arranged between the operation part 102 and the fixing part 1042. The fixing part 1042 is welded to the welding area 2064 of the frame 20,and the fixing part 1042 stretches the operation part 102 to hold and tighten the operation part 102, so as to keep the operation part 102 in a tight state. The transition part 1044 bonds with the tiling area 2062 and is configured to maintain a flatness of the operation part 102.A side surface of the operation part 102 facing away from the frame 20 is configured to bond with the glass substrate of a display device and is configured to apply a vapor deposition process to the glass substrate. The flatness of the operation part 102 has a tremendous influence on the result of the vapor deposition process. The non-operation part 104 is only configured to weld the frame 20 and to stretch the operation part 102, and is not configured to bond with the glass substrate. An influence of a flatness of the welding area 2064 with respect to the operation part 102 may be avoided, and may lead to a good vapor deposition result.

In one embodiment, the frame 20 further includes a bottom surface 208, wherein the bottom surface 208 is opposite to the tiling area 2062 and connects the outer wall 204 and the inner wall 202.The welding area 2064 is bent toward the bottom surface 208 with respect to the tiling area 2062. Specifically, the welding area 2064 is a flat surface, and the welding area 2064 is inclined to the tiling area 2062. Further, the smaller an angle form by the welding area 2064 and the tiling area 2062, i.e. A connection between the welding area 2064 and the tiling area 2062 is smoother, the smaller the deformation of the shadow mask film 10 caused by the frame 20 is, and the shadow mask film 10 is less likely to be damaged during the welding process and the vapor deposition process. The greater a bending angle of the welding area 2064 with respect to the tiling area 2062, the greater the tension received by the shadow mask film 10 and the higher the flatness of the shadow mask film 10 is.

The bonding surface 206 is divided into the welding area 2064 configured to weld the shadow mask film 10 and the tiling area 2062 configured to expand the shadow mask film 10, and the welding area 2064 and the tiling area 2062 are non-coplanar. The welding area 2064 is configured to fix and stretch the shadow mask film 10, and the shadow mask film 10 bonds with the tiling area 2062 to maintain the shadow mask film 10 to be a flat surface. A least one solder joint 30 of the original shadow mask film remains on the welding area 2064 has no influence on the flatness of the shadow mask film 10 upon changing a new shadow mask film 10, such that to enhance the deposition yield of AMOLED glass substrates and to reduce the production cost.

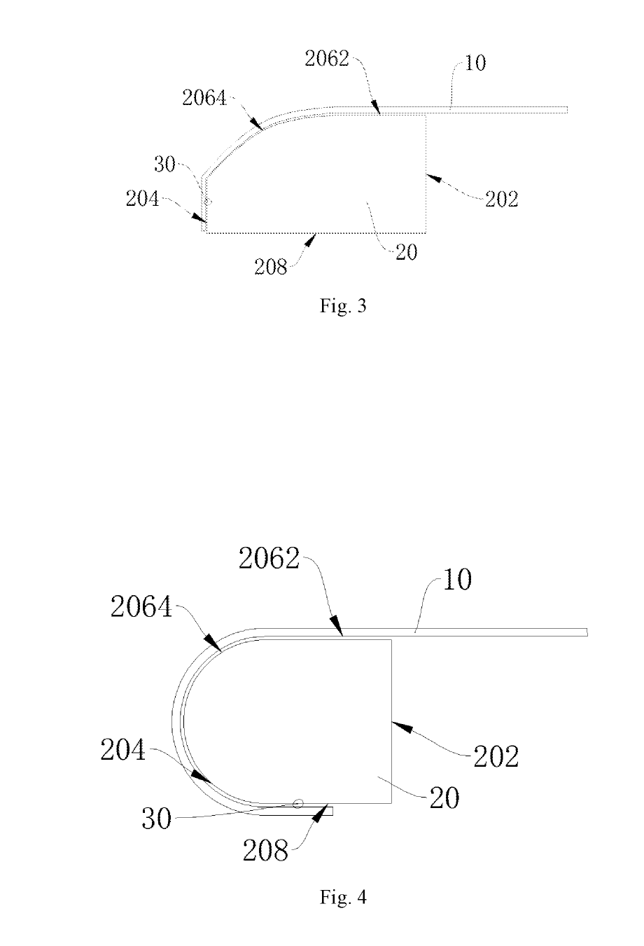

FIG. 2 is a schematic view of a cross-section of the shadow mask assembly in accordance with a second embodiment of the present disclosure. FIG. 2 only illustrates the schematic view of one side of the shadow mask assembly. The difference between the present embodiment and the first embodiment resides in that a cross-section of the welding area 2064 is an arc connecting the tiling area 2062 and the outer wall 204 in the present embodiment. The shadow mask film 10 is welded on the frame 20 via an arc shaped surface of the welding area 2064. The arc shaped welding area 2064 causes the edge of the shadow mask film 10 to be gently bent, such that to reduce the possibility of damaging the shadow mask film 10 by bending the shadow mask film 10 upon the shadow mask film 10 is welded.

The bonding surface 206 is divided into the welding area 2064 configured to weld the shadow mask film 10 and the tiling area 2062 configured to expand the shadow mask film 10, and the welding area 2064 and the tiling area 2062 are non-coplanar. The welding area 2064 is configured to fix and stretch the shadow mask film 10, and the shadow mask film 10 bonds with the tiling area 2062 to maintain the shadow mask film 10 to be a flat surface. A least one solder joint 30 of the original shadow mask film remains on the welding area 2064 has no influence on the flatness of the shadow mask film 10 upon changing a new shadow mask film 10, such that to enhance the deposition yield of AMOLED glass substrates and to reduce the production cost.

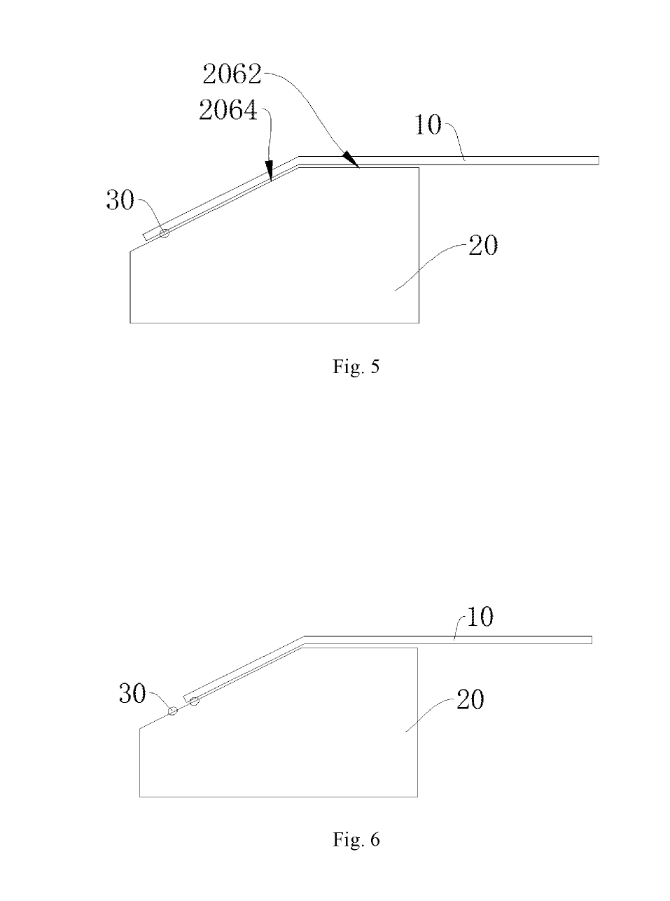

FIG. 3 is a schematic view of a cross-section of the shadow mask assembly in accordance with a third embodiment of the present disclosure. FIG. 3 only illustrates the schematic view of one side of the shadow mask assembly. The difference between the present embodiment and the second embodiment resides in that the solder joint 30 is also arranged on a sidewall and the fixing part 104 is fixed on the frame 20 via the solder joint 30 on the sidewall.

The bonding surface 206 is divided into the welding area 2064 configured to weld the shadow mask film 10 and the tiling area 2062 configured to expand the shadow mask film 10, and the welding area 2064 and the tiling area 2062 are non-coplanar. The welding area 2064 is configured to fix and stretch the shadow mask film 10, and the shadow mask film 10 bonds with the tiling area 2062 to maintain the shadow mask film 10 to be a flat surface. A least one solder joint 30 of the original shadow mask film remains on the welding area 2064 has no influence on the flatness of the shadow mask film 10 upon changing a new shadow mask film 10, such that to enhance the deposition yield of AMOLED glass substrates and to reduce the production cost.

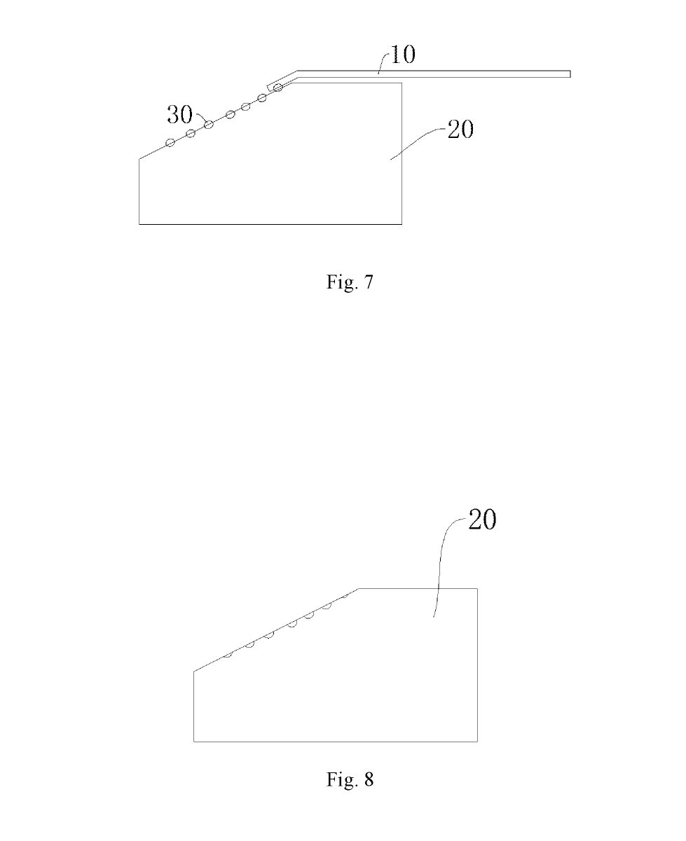

FIG. 4 is a schematic view of a cross-section of the shadow mask assembly in accordance with a fourth embodiment of the present disclosure. FIG. 4 only illustrates the schematic view of one side of the shadow mask assembly. The difference between the present embodiment and the third embodiment resides in that a cross-section of the sidewall is an arc having a curvature equal to the welding area 2064.A continuous arc is formed by the cross-section of the welding area 2064 and the cross-section of the sidewall, and the continuous arc connects the tiling area 2062 and the bottom surface 208. Further, the bottom surface 208 is also configured with the solder joint 30.The fixing part 104 is fixed on the frame 20 via the solder joint 30 on the bottom surface 208. The shadow mask film 10 bonds with the arc shaped sidewall and is bent gently, such that to reduce the possibility of damaging the shadow mask film 10 by bending the shadow mask film 10 upon the shadow mask film 10 is welded.

The bonding surface 206 is divided into the welding area 2064 configured to weld the shadow mask film 10 and the tiling area 2062 configured to expand the shadow mask film 10, and the welding area 2064 and the tiling area 2062 are non-coplanar. The welding area 2064 is configured to fix and stretch the shadow mask film 10, and the shadow mask film 10 bonds with the tiling area 2062 to maintain the shadow mask film 10 to be a flat surface. A least one solder joint 30 of the original shadow mask film remains on the welding area 2064 has no influence on the flatness of the shadow mask film 10 upon changing a new shadow mask film 10, such that to enhance the deposition yield of AMOLED glass substrates and to reduce the production cost.

In one aspect, a reusing method of shadow mask assemblies including: providing the shadow mask film 10 and the frame 20, and the frame includes the outer wall 204, an inner wall 202 arranged opposite to the outer wall 204, and the bonding surface 206 connecting the outer wall 204 and the inner wall 202.The bonding surface includes the welding area 2064 and the tiling area 2062, wherein the welding area 2064 and the tiling area 2062 are non-coplanar. The welding area 2064 is arranged between the tiling area 2062 and the outer wall 204, and the tiling area 2062 is arranged between the welding area 2064 and the inner wall 202.

In Step S101, fixing the frame 20 on the edge of the shadow mask film 10 via the welding area 2064, and forming the solder joint 30within the welding area 2064. The frame 20 maintains the shadow mask film 10 to be a flat surface via the tiling area 2062.

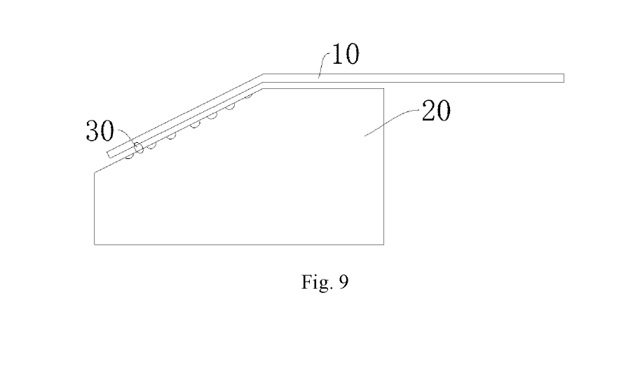

Referring to FIG. 5, the solder joint 30 is arranged within the welding area 2064, and the edge of the shadow mask film 10 connects the frame 20 via the solder joint 30.

In Step S102, bonding the glass substrate of the display device via the shadow mask film 10 and applying the vapor deposition process to the glass substrate.

The stretched and expanded shadow mask film 10 bonds with the glass substrate, and an organic light-emitting layer is deposited on the glass substrate by a vapor deposition apparatus.

In Step S103, removing the shadow mask film 10 from the frame 20 upon changing the shadow mask film 10and forming the new solder joint 30 via welding another shadow mask film 10 onto the welding area 2064.

Specifically, when defects appear after the shadow mask films 10 have been used for a plurality of times, removing the shadow mask films 10 and forming the new solder joint 30 by welding another shadow mask film 10 onto the welding area 2064. Positions of the solder joint 30 formed by the mask film 10 of each changes does not overlap.

Referring to FIG. 6 and FIG. 7, the new shadow mask film 10 is welded to the frame 20 by the new solder joint 30 of the welding area 2064 upon changing the shadow mask film 10, further, using the new solder joint 30 upon each times of changing the shadow mask film 10. Due to the flatness of the welding area 2064 has no influence on the flatness of the shadow mask film 10, the old solder joint 30 needs not to be polished, thereby to reduce times of polishing process.

In Step S104, applying the polishing process to all of the solder joints 30 at one time after the shadow mask films 10 have been changed for a plurality of times.

Referring to FIG. 7, FIG. 8, and FIG. 9, after the shadow mask films 10 have been changed for a plurality of times, a plurality of solder joints 30 are formed. Applying the polishing process to all of the solder joints 30 at one time can ensure the flatness of the welding area 2064 after polishing. The polished shadow mask film 10 is directly put into use again.

In one embodiment, the frame 20 further includes a bottom surface 208, wherein the bottom surface 208 is opposite to the tiling area 2062 and connects the outer wall 204 and the inner wall 202.The welding area 2064 is bent toward the bottom surface 208 with respect to the tiling area 2062. Specifically, the welding area 2064 is a flat surface, and the welding area 2064 is inclined to the tiling area 2062. Further, the smaller an angle form by the welding area 2064 and the tiling area 2062, i.e. A connection between the welding area 2064 and the tiling area 2062 is smoother, the smaller the deformation of the shadow mask film 10 caused by the frame is, and the shadow mask film 10 is less likely to be damaged during the welding process and the vapor deposition process. The greater a bending angle of the welding area 2064 with respect to the tiling area 2062, the greater the tension received by the shadow mask film 10 and the higher the flatness of the shadow mask film 10 is.

In one embodiment, the cross-section of the welding area 2064 is the arc connecting the tiling area 2062 and the outer wall 204 in the present embodiment. The shadow mask film 10 is welded on the frame 20 via the arc shaped surface of the welding area 2064. The arc shaped welding area 2064 causes the edge of the shadow mask film 10 to be gently bent, such that to reduce the possibility of damaging the shadow mask film 10 by bending the shadow mask film 10 upon the shadow mask film 10 is welded.

The bonding surface 206 is divided into the welding area 2064 configured to weld the shadow mask film 10 and the tiling area 2062 configured to expand the shadow mask film 10, and the welding area 2064 and the tiling area 2062 are non-coplanar. The welding area 2064 is configured to fix and stretch the shadow mask film 10, and the shadow mask film 10 bonds with the tiling area 2062 to maintain the shadow mask film 10 to be a flat surface. A least one solder joint 30 of the original shadow mask film remains on the welding area 2064 has no influence on the flatness of the shadow mask film 10 upon changing a new shadow mask film 10, such that to enhance the deposition yield of AMOLED glass substrates and to reduce the production cost.

Above are embodiments of the present invention, which does not limit the scope of the present invention. Any modifications, equivalent replacements or improvements within the spirit and principles of the embodiment described above should be covered by the protected scope of the invention.

What is claimed is:

1. A shadow mask assembly, comprising:
a shadow mask film and a frame, and the frame comprising an outer wall, an inner wall arranged opposite to the outer wall, and a bonding surface connecting the outer wall and the inner wall, wherein the bonding surface bonds with the shadow mask film, and the bonding surface comprises a welding area and a tiling area, wherein the welding area and the tiling area are non-coplanar, the welding area is arranged between the tiling area and the outer wall, the frame is fixed on at least one edge of the shadow mask film via at least one solder joint arranged within the welding area, the tiling area is arranged between the welding area and the inner wall, and the tiling area is configured to support the shadow mask film and to maintain the shadow mask film to be a flat surface.

2. The shadow mask assembly according to claim 1, wherein the shadow mask film comprises an operation part and a non-operation part connecting to an edge of the operation part, the non-operation part bonds with the bonding surface, the non-operation part comprises a fixing part and a transition part, the transition part is arranged between the operation part and the fixing part, the fixing part is welded to the welding area of the frame and keeps the operation part in a tight state, the transition part bonds with the tiling area and is configured to maintain a flatness of the operation part, a side surface of the operation part facing away from the frame is configured to bond with a glass substrate of a display device and is configured to apply a vapor deposition process to the glass substrate.

3. The shadow mask assembly according to claim 2, wherein the frame further comprises a bottom surface, the bottom surface is opposite to the tiling area and connects the outer wall and the inner wall, and the welding area is bent toward the bottom surface with respect to the tiling area.

4. The shadow mask assembly according to claim 2, wherein a cross-section of the welding area is an arc connecting the tiling area and the outer wall.

5. The shadow mask assembly according to claim 4, wherein the solder joint is also arranged on a sidewall, the fixing part is fixed on the frame via the solder joint on the sidewall.

6. The shadow mask assembly according to claim 5, wherein a cross-section of the side wall is an arc having a curvature equal to the welding area, a continuous arc is formed by the cross-section of the welding area and the cross-section of the sidewall, and the continuous arc connects the tiling area and the bottom surface.

7. The shadow mask assembly according to claim 6, wherein the bottom surface is also configured with the solder joint, the fixing part is fixed on the frame via the solder joint on the bottom surface.

8. A reusing method of shadow mask assemblies, comprising:
providing a shadow mask film and a frame, and the frame comprising an outer wall, an inner wall arranged opposite to the outer wall, and a bonding surface connecting the outer wall and the inner wall, the bonding surface comprises a welding area and a tiling area, wherein the welding area and the tiling area are non-coplanar, the welding area is arranged between the tiling area and the outer wall, and the tiling area is arranged between the welding area and the inner wall;
fixing the frame on at least one edge of the shadow mask film via the welding area, and at least one solder joint is arranged within the welding area, the frame maintains the shadow mask film to be a flat surface via the tiling area;
bonding a glass substrate of a display device via the shadow mask film and applying a vapor deposition process to the glass substrate,
removing the shadow mask film from the frame upon changing the shadow mask film, forming a new solder joint by welding another shadow mask film onto the welding area, applying a polishing process to all of the solder joints at one time after the shadow mask films have been changed for a plurality of times.

9. The reusing method of shadow mask assemblies according to claim 8, wherein the frame comprises a bottom surface, wherein the bottom surface is opposite to the tiling area and connects the outer wall and the inner wall, and the welding area is bent toward the bottom surface with respect to the tiling area.

10. The reusing method of shadow mask assemblies according to claim 8, wherein a cross-section of the welding area is an arc connecting the tiling area and the outer wall.

11. The reusing method of shadow mask assemblies according to claim 10, wherein the solder joint is also arranged on a sidewall, the fixing part is fixed on the frame via the solder joint on the sidewall.

12. The reusing method of shadow mask assemblies according to claim 11, wherein a cross-section of the sidewall is an arc having a curvature equal to the welding area, a continuous arc is formed between the cross-section of the welding area and the cross-section of the sidewall, and the continuous arc connects the tiling area and the bottom surface.

13. The reusing method of shadow mask assemblies according to claim 12, wherein the bottom surface is also configured with the solder joint, the fixing part is fixed on the frame via the solder joint on the bottom surface.
